(19) United States
(12) Patent Application Publication
(10) Pub. No.: US 2024/0113079 A1
(43) Pub. Date: Apr. 4, 2024

(54) SEMICONDUCTOR DEVICE

(71) Applicant: LAPIS Technology Co., Ltd., Yokohama-shi (JP)

(72) Inventor: Eikichi SHIMIZU, Yokohama-shi (JP)

(73) Assignee: LAPIS Technology Co., Ltd., Yokohama-shi (JP)

(21) Appl. No.: 18/473,582

(22) Filed: Sep. 25, 2023

(30) Foreign Application Priority Data
Sep. 30, 2022 (JP) 2022-158776

(51) Int. Cl. H01L 25/065; H01L 23/00

(52) U.S. Cl. CPC H01L 25/0657; H01L 24/08; H01L 2224/08145; H01L 2924/13091

(57) ABSTRACT

A semiconductor device, including: a first chip and a second chip that are joined together, a plurality of power domains being configured in the first chip, wherein: the first chip includes a plurality of individual switches and a first connection terminal, the plurality of individual switches being provided in respective correspondence with the plurality of power domains, and the first connection terminal being connected in common to the plurality of individual switches, and the second chip includes a second connection terminal and a common switch, the second connection terminal being connected to the first connection terminal, the common switch being provided between a power supply and the second connection terminal.

### CROSS-REFERENCE TO RELATED APPLICATION

This application is based on and claims priority under 35 USC 119 from Japanese Patent Application No. 2022-158776 filed on Sep. 30, 2022, the disclosure of which is incorporated by reference herein.

### BACKGROUND

### Technical Field

The present disclosure relates to a semiconductor device.

### Related Art

In a semiconductor device, process sizes need to be further reduced for greater levels of integration. Correspondingly, declines in energy efficiency performance due to leakage currents at components formed in semiconductor devices are becoming more conspicuous.

As a response to this problem, a semiconductor device is proposed in Japanese Patent Application Laid-Open (JP-A) No. 2008-60370 in which plural semiconductor chips with different functions are connected and mounted in a single package. This semiconductor device is provided with disconnecting means for stopping supply of a power supply voltage from one to another of the semiconductor chips.

In recent years, in order to improve energy efficiency, semiconductor devices have been implemented in which plural power domains are specified within a semiconductor device and the semiconductor device is capable of switching supply from a power supply to each power domain on and off.

When, in a semiconductor device in which plural semiconductor chips are connected, plural domains are specified in a semiconductor chip with a smaller process size, if switches for switching supply from a power supply to the respective power domains on and off are provided in that semiconductor chip with the smaller process size, energy efficiency performance declines due to leakage currents at components structuring the switches.

Accordingly, disposing the switches in a semiconductor chip with a larger process size to suppress the effects of leakage currents at components structuring the switches can be considered.

In this mode, however, connection terminals for connecting supply lines from the power supply between the semiconductor chips must be respectively provided for the power domains. As a result, a number of connection terminals increases and the connection terminals occupy areas of the semiconductor chips.

### SUMMARY

The present disclosure provides a semiconductor device in which plural semiconductor chips are connected, which semiconductor device achieves an improvement in energy efficiency while restraining a number of connection terminals between chips.

A semiconductor device of a first aspect is a semiconductor device that includes: a first chip and a second chip that are joined together, plural power domains being configured in the first chip, and leakage currents being smaller in the second chip than in the first chip, wherein: the first chip includes plural individual switches and a first connection terminal, the plural individual switches being provided in respective correspondence with the plural power domains, each of the individual switches switching between a state of supplying a power supply voltage to the power domain and a state of not supplying the power supply voltage, and the first connection terminal being connected in common to the plural individual switches, and the second chip includes a second connection terminal and a common switch, the second connection terminal being connected to the first connection terminal, the common switch being provided between a power supply and the second connection terminal, and the common switch switching between a state of supplying the power supply voltage in common to the plural power domains and a state of not supplying the power supply voltage.

In a semiconductor device of a second aspect, in the semiconductor device according to the first aspect, the first chip is formed with a first process size, and the second chip is formed with a second process size that is larger than the first process size.

In a semiconductor device of a third aspect, in the semiconductor device according to the first aspect or the second aspect, the first chip includes an external connection terminal that connects from outside the first chip to between the first connection terminal and the plural individual switches.

According to the semiconductor device of the present disclosure, in a semiconductor device in which plural semiconductor chips are connected, an improvement in energy efficiency may be achieved while a number of connection terminals between chips may be restrained.

### BRIEF DESCRIPTION OF THE DRAWINGS

An exemplary embodiment of the present disclosure will be described in detail based on the following figures, wherein:

FIG. 1 is a diagram showing schematic structures of a semiconductor device according to a first exemplary embodiment of the present disclosure; and

FIG. 2 is a diagram showing schematic structures of a semiconductor device according to a comparative example.

### DETAILED DESCRIPTION

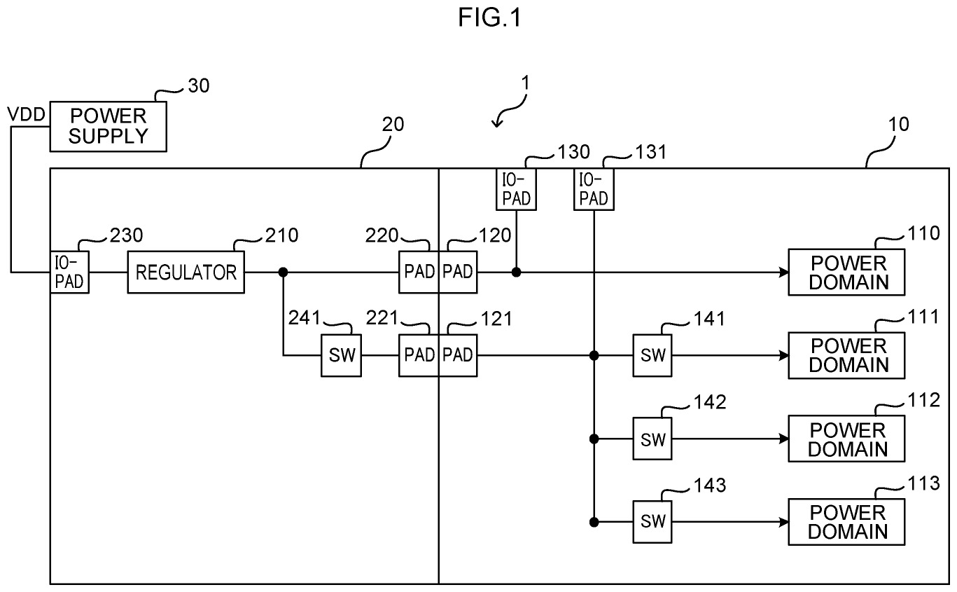

Now, an exemplary embodiment of the present disclosure is described with reference to the drawings. FIG. 1 is a diagram showing schematic structures of a semiconductor device 1 according to a first exemplary embodiment of the present disclosure.

As shown in FIG. 1, in the semiconductor device 1 according to the present exemplary embodiment, a first chip 10 and a second chip 20 are joined together by die-to-wafer bonding.

The meaning of the term “die-to-wafer bonding” as used herein is intended to include joining in a state in which the first chip 10 and the second chip 20 are stacked and plural connection terminals 120 and 121 formed at the first chip 10 are directly connected to each of plural connection terminals 220 and 221 formed at the second chip 20.

The first chip 10 is a semiconductor chip formed with a process size of 22 nm, which is an example of a first process size. Plural power domains are specified in the first chip 10.

The meaning of the term “process size” as used herein is intended to include a minimum feature size in fabrication of a semiconductor chip, specifically a size of line widths, transistor gate lengths or the like within the semiconductor chip. The smaller the process size, the greater are leakage currents at components formed in the semiconductor chip. A process size can also be referred to as a process rule.

The meaning of the term “power domain” is intended to include a region of a semiconductor chip that is operated by a single power supply system. In the first chip 10 according to the present exemplary embodiment, different power domains 110, 111, 112 and 113 are specified for respective functional blocks.

The first chip 10 is provided with plural individual switches (marked with “SW” in FIGS. 1) 141, 142 and 143 and the connection terminal 121 (marked with “PAD” in FIG. 1). The individual switches 141, 142 and 143 are provided at, respectively, the power domains 111, 112 and 113, and each switches between a state of supplying a power supply voltage to the power domain and a state of not supplying the power supply voltage. The connection terminal 121 is connected to all of the plural individual switches 141, 142 and 143. The connection terminal 121 is an example of a first connection terminal of the technology of the present disclosure.

The individual switches 141, 142 and 143 are structured by switch elements formed of, for example, metal-oxide-semiconductor (MOS) transistors. When the individual switch 141, 142 or 143 is in an on state, a power supply voltage is supplied to the power domain 111, 112 or 113, and when the individual switch 141, 142 or 143 is in an off state, the power supply voltage is not supplied to the power domain 111, 112 or 113.

The power domain 110 is a region to which the power supply voltage is permanently supplied. Therefore, no individual switch is provided for the power domain 110.

The second chip 20 is a semiconductor chip formed with a process size of 130 nm, which is an example of a second process size.

The second chip 20 is provided with the connection terminal 221, which is connected to the connection terminal 121, and a common switch 241, which is provided between a power supply 30 and the connection terminal 221. The common switch 241 switches between a state of supplying the power supply voltage in common to the power domains 111, 112 and 113 and a state of not supplying the power supply voltage. The connection terminal 221 is an example of the first connection terminal of the technology of the present disclosure.

The common switch 241 is structured by a switch element formed of, for example, a MOS transistor. When the common switch 241 is in the on state, the power supply voltage is supplied to the power domains 111, 112 and 113, and when the common switch 241 is in the off state, the power supply voltage is not supplied to the power domains 111, 112 and 113.

A power supply voltage VDD supplied from the power supply 30 is inputted to the second chip 20 via an external connection terminal (marked with “IO-PAD” in FIG. 1) 230, is converted by a regulator 210 to a power supply voltage that is required in the first chip 10 and the second chip 20, and is then supplied to each of the power domains 110, 111, 112 and 113 of the second chip 20.

The power supply voltage that is outputted from the regulator 210 as described above is supplied to the power domain 110 via only the connection terminals 120 and 220, without passing through a switch, and is supplied to the power domains 111, 112 and 113 via the common switch 241, the connection terminals 121 and 221, and the individual switches 141, 142 and 143.

The first chip 10 is further provided with an external connection terminal 130 and an external connection terminal 131. The external connection terminal 130 is for connection from outside the first chip 10 to between the connection terminal 120 and the power domain 110. The external connection terminal 131 is for connection from outside the first chip 10 to between the connection terminal 121 and the individual switches 141, 142 and 143.

The external connection terminals 130 and 131 are for supplying power supply voltages from outside during testing of operations of the first chip 10 in a standalone state in which the first chip 10 is not joined to the second chip 20.

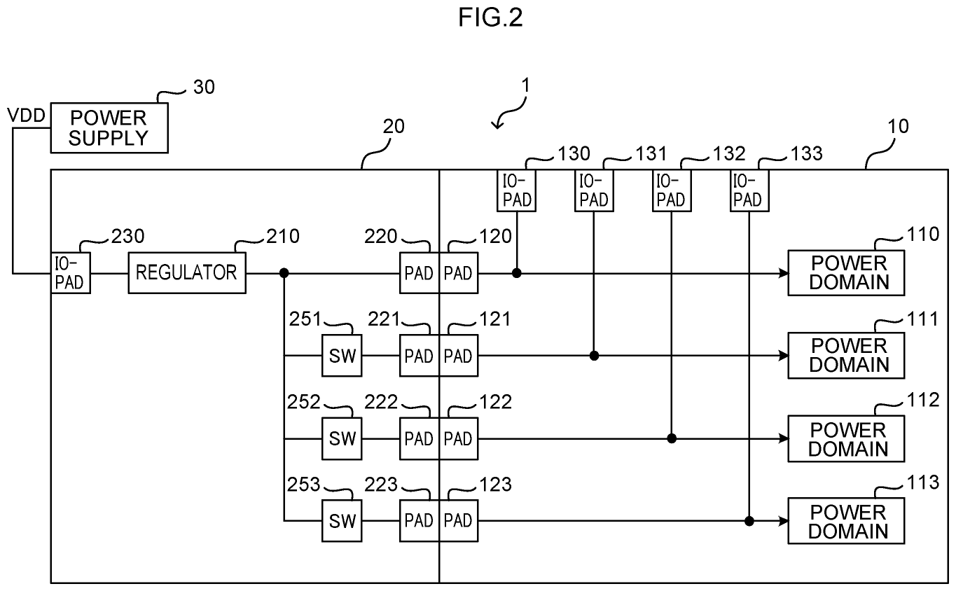

Now, a semiconductor device 100 according to a comparative example is described to aid understanding of effects of the semiconductor device 1 according to the present exemplary embodiment. FIG. 2 is a diagram showing structures of the semiconductor device 100 according to the comparative example.

As shown in FIG. 2, the semiconductor device 100 according to the comparative example differs from the semiconductor device 1 according to the present exemplary embodiment in a mode of disposition of switches that switch supply states of the power supply voltage to the power domains 111, 112 and 113.

In the semiconductor device 100 according to the comparative example, individual switches 251, 252 and 253 are provided in the second chip 20. The individual switches 251, 252 and 253 are provided for, respectively, the power domains 111, 112 and 113, and each switches between a state of supplying the power supply voltage to the power domain and a state of not supplying the power supply voltage. In the semiconductor device 100, no common switch is provided for switching between a state of supplying the power supply voltage to all of the power domains 111, 112 and 113 and a state of not supplying the power supply voltage.

In other respects, structures are the same as in the semiconductor device 1 according to the present exemplary embodiment and are not described.

The second chip 20 has a larger process size than the first chip 10. In general, leakage currents are smaller in a chip with a larger process size than in a chip with a smaller process size. Therefore, providing a switch for switching the supply state of a power supply voltage at the second chip 20 may suppress leakage current at the switch when supply from the power supply is stopped.

When the individual switches 251, 252 and 253 are provided in the second chip 20 as in the semiconductor device 100 according to the comparative example, the effects of leakage currents are suppressed and supply states from the power supply to the power domains 111, 112 and 113 may be controlled individually.

In this structure, however, three pairs of connection terminals between the first chip 10 and the second chip 20 (the connection terminals 121 and 221, the connection terminals 122 and 222, and the connection terminals 123 and 223) are required, and these occupy areas of the first chip 10 and the second chip 20.

Moreover, when external connection terminals are provided for testing of operations of the power domains 111, 112 and 113 of the first chip 10 in the standalone state, three external connection terminals 131, 132 and 133 are required, and these occupy areas of the first chip 10.

Terminal areas of the external connection terminals 131, 132 and 133 are greater than terminal areas of the connection terminals 121 and 221, connection terminals 122 and 222 and connection terminals 123 and 223 that connect between the first chip 10 and the second chip 20. Therefore, the external connection terminals 131, 132 and 133 occupy a greater area of the first chip 10.

In contrast, in the semiconductor device 1 according to the present exemplary embodiment, the individual switches 141, 142 and 143 are provided in the first chip 10 and the common switch 241 is provided in the second chip 20.

According to this mode, the supply state from the power supply to all of the power domains 111, 112 and 113 may be controlled by the common switch 241 in the second chip 20 that has smaller leakage current, and the supply states from the power supply to the power domains 111, 112 and 113 may be individually controlled by the individual switches 141, 142 and 143 in the first chip 10.

Further, according to this mode, because one pair of connection terminals between the first chip 10 and the second chip 20 (at the connection terminal 121) is sufficient, occupied area of the first chip 10 and second chip 20 may be restrained.

Even when an external connection terminal is provided for testing of operations of the power domains 111, 112 and 113 of the first chip 10 in the standalone state, because the single external connection terminal 131 is sufficient, occupied areas of the first chip 10 may be restrained.

As described above, because the terminal area of the external connection terminal 131 is larger than terminal areas of the connection terminals 121 and 221 that connect between the first chip 10 and the second chip 20, the effect of restraining occupied area of the first chip 10 is more remarkable.

In the semiconductor device 1 according to the present exemplary embodiment, the process size of the second chip 20 is larger than the process size of the first chip 10. However, the present exemplary embodiment is not limiting and any mode is applicable given process sizes or structures such that leakage currents in the second chip 20 are smaller than leakage currents in the first chip 10.

The details recited above and the details shown in the drawings are detailed descriptions of portions relating to the technology of the present disclosure and are merely an example of the technology of the present disclosure. For example, the above descriptions relating to structures, functions, operations and effects are descriptions relating to examples of structures, functions, operations and effects of the portions relating to the technology of the present disclosure. Accordingly, it will be clear that unnecessary portions may be removed from the details recited above and the details shown in the drawings and that new elements may be added or substituted within a scope that does not depart from the gist of the technology of the present disclosure. Furthermore, in order to avoid complication and facilitate understanding of portions relating to the technology of the present disclosure, in the details recited above and details shown in the drawings, descriptions are not given of common technical knowledge and the like that is not particularly required for enabling the technology of the present disclosure.

What is claimed is:

1. A semiconductor device, comprising:
a first chip and a second chip that are joined together, a plurality of power domains being configured in the first chip, and leakage currents being smaller in the second chip than in the first chip, wherein:
the first chip includes a plurality of individual switches and a first connection terminal,
the plurality of individual switches being provided in respective correspondence with the plurality of power domains,
each of the individual switches switching between a state of supplying a power supply voltage to the power domain and a state of not supplying the power supply voltage, and
the first connection terminal being connected in common to the plurality of individual switches, and
the second chip includes a second connection terminal and a common switch,
the second connection terminal being connected to the first connection terminal,
the common switch being provided between a power supply and the second connection terminal, and
the common switch switching between a state of supplying the power supply voltage in common to the plurality of power domains and a state of not supplying the power supply voltage.

2. The semiconductor device according to claim 1, wherein:
the first chip is formed with a first process size, and
the second chip is formed with a second process size that is larger than the first process size.

3. The semiconductor device according to claim 1, wherein the first chip includes an external connection terminal that connects from outside the first chip to between the first connection terminal and the plurality of individual switches.
